(19) United States
(12) Patent Application Publication
(10) Pub. No.: US 2012/0031490 A1
(43) Pub. Date: Feb. 9, 2012

(54) QUANTUM DOT SOLAR CELLS AND METHODS FOR MANUFACTURING SUCH SOLAR CELLS

(75) Inventors: Anna Liu, Shanghai (CN); Zhi Zheng, Shanghai (CN); Linan Zhao, Shanghai (CN); Marilyn Wang, Shanghai (CN)

(73) Assignee: HONEYWELL INTERNATIONAL INC., Morristown, NJ (US)

(21) Appl. No.: 12/849,719

(22) Filed: Aug. 3, 2010

(51) Int. Cl. H01L 31/0296; H01L 31/18

(52) U.S. Cl. 136/260; 438/95; 257/E31.015; 977/774; 977/948

(57) ABSTRACT

Solar cells, methods for manufacturing a quantum dot layer for a solar cell, and methods for manufacturing solar cells are disclosed. An illustrative method for manufacturing a solar cell may include dissolving a cadmium-containing compound in a first non-aqueous solvent to form a cadmium precursor solution, dissolving a selenium-containing compound in a second non-aqueous solvent to form a selenium precursor solution, combining the cadmium precursor solution with the selenium precursor solution to form a mixed solution, and exposing an electron conductor film to the mixed solution. Exposing the electron conductor film to the mixed solution may cause a cadmium and selenium quantum dot layer to be provided on the electron conductor film. This is just one example method.

### TECHNICAL FIELD

The disclosure relates generally to solar cells. More particularly, the disclosure relates to quantum dot solar cells.

### BACKGROUND

A wide variety of solar cells have been developed for converting sunlight into electricity. Of the known solar cells, each has certain advantages and disadvantages. There is an ongoing need to provide alternative solar cells as well as alternative methods for manufacturing solar cells.

### SUMMARY

The disclosure relates generally to solar cells, methods for manufacturing a quantum dot layer for a solar cell, and methods for manufacturing solar cells. An illustrative method for manufacturing a solar cell may include, for example, dissolving a cadmium-containing compound in a first non-aqueous solvent to form a cadmium precursor solution, dissolving a selenium-containing compound in a second non-aqueous solvent to form a selenium precursor solution, combining the cadmium precursor solution with the selenium precursor solution to form a mixed solution, and exposing an electron conductor film to the mixed solution. Exposing the electron conductor film to the mixed solution may cause a cadmium and selenium quantum dot layer to be provided on the electron conductor film.

Another illustrative method for manufacturing a solar cell may include, for example, providing a cadmium-containing compound, providing a selenium-containing compound, providing a non-aqueous solvent, combining the cadmium-containing compound, the selenium-containing compound, and the non-aqueous solvent to form a mixed solution, exposing an electron conductor film of a solar cell to the mixed solution to provide a quantum dot layer on the electron conductor film, and in some cases, disposing a shell on the electron conductor film that has the cadmium and selenium quantum dot layer deposited thereon. In some cases, the quantum dot layer may include a plurality of CdSe quantum dots.

An illustrative quantum dot solar cell may include, for example, an electron conductor film having a mesoporous surface. A quantum dot layer may be deposited on the mesoporous surface using a single-step dip coating process where the electron conductor film is dipped into a mixed solution. The mixed solution may be formed by, for example, providing a cadmium-containing compound, providing a selenium-containing compound, providing a non-aqueous solvent, and combining the cadmium-containing compound, the selenium-containing compound, and the non-aqueous solvent to form a mixed solution.

The above summary is not intended to describe each and every disclosed embodiment or every implementation of the disclosure. The Figures and Description which follow more particularly exemplify certain illustrative embodiments.

### BRIEF DESCRIPTION OF THE DRAWINGS

The invention may be more completely understood in consideration of the following detailed description of various embodiments of the invention in connection with the accompanying drawings, in which:

FIG. 1 is a schematic cross-sectional side view of an illustrative but non-limiting example of a solar cell; and

FIG. 2 is a schematic cross-sectional side view of another illustrative but non-limiting example of a solar cell.

While the disclosure is amenable to various modifications and alternative forms, specifics thereof have been shown by way of example in the drawing and will be described in detail. It should be understood, however, that the intention is not to limit the invention to the particular embodiments or examples described. On the contrary, the intention is to cover all modifications, equivalents, and alternatives falling within the spirit and scope of the disclosure.

### DESCRIPTION

The following description should be read with reference to the drawings in which similar elements in different drawings are numbered the same. The drawings, which are not necessarily to scale, depict certain illustrative embodiments and are not intended to limit the scope of the invention.

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

A wide variety of solar cells (which also may be known as photovoltaics and/or photovoltaic cells) have been developed for converting sunlight into electricity. Some example solar cells include a layer of crystalline silicon. Second and third generation solar cells often utilize a thin film of photovoltaic material (e.g., a “thin” film) deposited or otherwise provided on a substrate. These solar cells may be categorized according to the photovoltaic material deposited. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

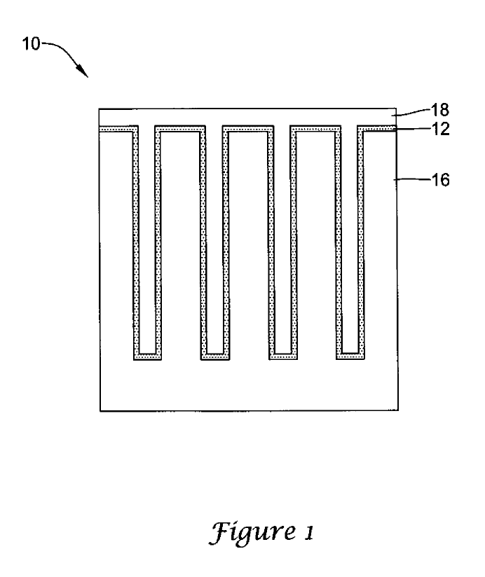

FIG. 1 is a schematic cross-sectional side view of an illustrative solar cell 10. In the illustrative example shown in FIG. 1, there may be a three-dimensional intermingling or interpenetration of the various layers forming solar cell 10, but this is not required. The illustrative solar cell 10 includes a quantum dot layer 12. Quantum dot layer 12 may be considered as representing a plurality of individual quantum dots. The illustrative solar cell 10 may also include an electron conductor layer 16. In some cases, electron conductor layer 16 may be an n-type conductor. While not required, a bifunctional ligand layer (not shown) may be disposed between electron conductor layer 16 and quantum dot layer 12. The bifunctional ligand layer may include a number of bifunctional ligands that are coupled to electron conductor layer 16 and to quantum dot layer 12. The illustrative solar cell 10 may further include a hole conductor layer 18. Hole conductor layer 18 may be a p-type conducting layer. In some cases, a first electrode (not explicitly shown) may be electrically coupled to the electron conductor layer 16, and a second electrode (not explicitly shown) may be coupled to the hole conductor layer 18, but this is not required in all embodiments. It is contemplated that solar cell 10 may include other structures, features and/or constructions, as desired.

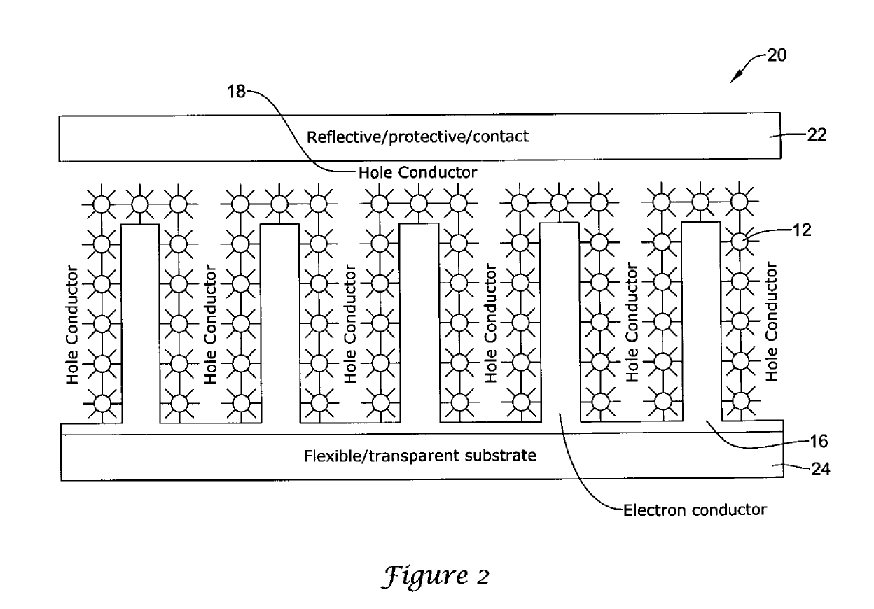

FIG. 2 is a schematic cross-sectional side view of an illustrative solar cell 20 that is similar to solar cell 10 (FIG. 1). In some cases, a reflective and/or protecting layer 22 may be disposed over the hole conductor layer 18, as shown. When layer 22 is reflective, light may enter the solar cell 20 from the bottom, e.g. through the flexible/transparent substrate 24. Some of the light may pass through the active layer 12, which may then be reflected back to the active layer 12 by the reflective layer 22, thereby increasing the efficiency of the solar cell 20. When provided, the reflective and/or protecting layer 22 may be a conductive layer, and in some cases, may act as the second electrode discussed above with respect to FIG. 1. In some instances, the reflective and/or protecting layer 22 may include a Pt/Au/C film as both catalyst and conductor, but this is not required. The reflective and/or protecting layer 22 is optional.

In some embodiments, solar cell 10 may include one or more substrates (e.g., substrates 22/24) and/or electrodes as is typical of solar cells. These structures may be made from a variety of materials including polymers, glass, and/or transparent materials polyethylene terephthalate, polyimide, low-iron glass, fluorine-doped tin oxide, indium tin oxide, Al-doped zinc oxide, a transparent conductive oxide, metal foils, Pt, other substrates coated with metal (e.g., Al, Au, etc.), any other suitable conductive inorganic element or compound, conductive polymer, and other electrically conductive material, or any other suitable material.

In the illustrative embodiment of FIG. 2, electron conductor layer 16 may be in electrical communication with the flexible and transparent substrate 24, but this is not required. A quantum dot layer 12 may be provided over the electron conductor layer, followed by a hole conductor layer 18 as discussed above. As noted above, there may be a three-dimensional intermingling or interpenetration of certain layers forming solar cell 20, but this is not required.

In some cases, the electron conductor layer 16 may be a metallic and/or semiconducting material, such as TiO₂ or ZnO. Alternatively, electron conductor layer 16 may be an electrically conducting polymer such as a polymer that has been doped to be electrically conducting and/or to improve its electrical conductivity. Electron conductor layer 16 may include an n-type conductor and/or form or otherwise be adjacent to the anode (negative electrode) of cell 20. In at least some embodiments, electron conductor layer 16 may be formed or otherwise include a structured pattern or array of, for example, nanoparticles, nanopillars, nanowires, or the like, as shown. In addition or in the alternative, electron conductor layer 16 may include a structure having a plurality of nanopores and/or mesopores.

Hole conductor layer 18 may include a p-type conductor and/or form or otherwise be adjacent to the cathode (positive electrode) of cell 20. In some instances, hole conductor layer 18 may be a conductive polymer, but this is not required. The conductive polymer may, for example, be or otherwise include a functionalized polythiophene. An illustrative but non-limiting example of a suitable conductive polymer has

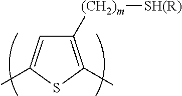

as a repeating unit, where R is absent or alkyl and m is an integer ranging from about 6 to about 12. The term “alkyl” refers to a straight or branched chain monovalent hydrocarbon radical having a specified number of carbon atoms. Examples of “alkyl” include, but are not limited to, methyl, ethyl, n-propyl, isopropyl, n-butyl, s-butyl, t-butyl, n-pentyl, n-hexyl, 3-methylpentyl, and the like.

Another illustrative but non-limiting example of a suitable conductive polymer has

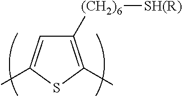

as a repeating unit, where R is absent or alkyl.

Another illustrative but non-limiting example of a suitable conductive polymer has

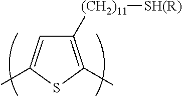

as a repeating unit, where R is absent or alkyl.

Another illustrative but non-limiting example of a suitable conductive polymer has

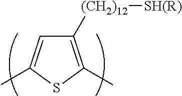

as a repeating unit, where R is absent or alkyl.

The quantum dot layer 12 may include a plurality of quantum dots. Quantum dots are typically very small semiconductors, having dimensions in the nanometer range. Because of their small size, quantum dots may exhibit quantum behaviors that are distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique. Examples of specific pairs of materials for forming quantum dots include, but are not limited to, MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs and InSb.

Disposing quantum dots or a quantum dot layer onto an electron conductor layer or film may include a chemical bath deposition process. In some cases, this may include, for example, providing a structured or mesoporous TiO₂ film and dipping or otherwise coating the film, in sequence, into aqueous solutions of the reactants. For example, if the quantum dots to be deposited are CdSe quantum dots, dipping may include dipping the film into aqueous solutions of Cd(NO₃)₂ and Na₂SeSO₃, respectively. It is believed that the ionic reactants (e.g., Cd²⁺ and Se²⁻) may penetrate into the porous structure of the TiO₂ film and incorporate into the inner region of the mesopores on the film. However, aqueous solutions may have a relatively high surface tension. Because of this, the solution may have a poor wetting ability on a solid surface, which may lead to relatively poor penetration of the solutions into a porous matrix. In addition, and in some cases, such processes may deposit a non-continuous quantum dot layer on the film with portions of the TiO₂ film being left uncovered.

In some cases, a new deposition process may be useful for depositing quantum dot layers such as quantum dot layer 12 onto electron conductor films such as electron conductor 16. In one illustrative method, which is summarized below, may result in greater wetting ability on a structured or mesoporous surface, greater penetration into the electron conductor layer or film, enhanced adhesion of quantum dot layer 12 onto electron conductor 16, and/or more continuous coverage of the electron conductor layer or film. A number of other desirable benefits may also be realized.

An illustrative chemical bath deposition may include providing a suitable substrate such as electron conductor layer 16 and depositing quantum dot layer 12 on electron conductor layer 16. In some cases, electron conductor layer 16 may be prepared by immersing electron conductor layer 16 in NH₄F for a few minutes (e.g., about 3-5 minutes). Additionally, preparation of electron conductor layer 16 may include and/or be followed by washing electron conductor layer 16 (e.g., with deionized water) and drying. In some embodiments, electron conductor layer 16 may be a film having a thickness of about 1-10 micrometers, but this is just one example.

The illustrative method may include providing a quantum dot chemical bath deposition solution (which may include CdSe, for example) in a suitable vessel or bottle. In some embodiments, the chemical bath deposition solution may be a “mixed solution”. When so provided, the chemical bath deposition solution may occur as a singular step. In other words, both components of quantum dot layer 12 (e.g., Cd and Se for CdSe quantum dots) may be provided in the mixed solution so that deposition can take place in a single “combined” dipping step, for example, rather than a series of individual dipping steps. The single step chemical bath deposition may be desirable for a number of reasons. For example, a single step process may be relatively simply, relatively low in cost, have a relatively high utilization of raw materials, have high control and repeatability, and/or may be relative easy to scale up and implement on a large scale.

In some embodiments, forming the mixed solution may include a number of steps. These steps may include, for example, providing cadmium, a source of cadmium, and/or a cadmium-containing compound. In one example, the cadmium-containing compound may include one or more of a cadmium-selenium compound, a cadmium-halogen compound, CdSe, CdS, CdTe, CdCl₂, CdBr₂, and Cd(CH₃CO₂)₂. The method may also include providing selenium, a source of selenium, and/or a selenium-containing compound. In one example, the selenium-containing compound may include one or more of a senium-amine compound, a selenium-hydrazine compound, H₂Se, Na₂SeSO₃, selenourea, and a selenium-containing hydrazine compound. The method may also include dissolving the cadmium, source of cadmium, and/or cadmium-containing compound in a first non-aqueous solvent to form a cadmium precursor solution. The first non-aqueous solvent may be a solvent containing a strong ligand. For example, the first non-aqueous solvent may include one or more of ammonia, a hydrazine compound (e.g., hydrazine, R₁R₂N—NR₃R₄ where, R₁, R₂, R₃, and R₄ are each independently selected from a group comprising H and any suitable C₁-C₂₀ alkyl group) alcohol, ethanolamine, diethanolamine, triethanolamine, isopropanol amine, formamide, N,N-dimethyl-formamide, acetamide, N-methyl acetamide, N,N-dimethylacetamide, dimethyl sulfoxide, and polyvinylpyrrolidone. The method may also include dissolving the selenium and/or selenium-containing compound in a second non-aqueous solvent to form a selenium precursor solution. The second non-aqueous solvent may be the same or different from the first non-aqueous solvent.

In some cases, the use of non-aqueous solvents may be desirable for a number of reasons. For example, non-aqueous solvent may have reduced surface tension (relative to aqueous solvents) so that each of the reactants, dissolved in a suitable non-aqueous solvent, may have improved wetting ability and/or penetration into a structured or mesoporous electron conductor layer 16.

The method may also include combining the cadmium precursor solution with the selenium precursor solution to form a mixed solution. This may include the use of a co-solvent and/or a co-solvent process. For example, if any of the reactants are not fully dissolved in the non-aqueous solvents utilized, another solvent or “co-solvent” can be added to further dissolve remaining solute. When provided, essentially any suitable co-solvent may be utilized including, for example, sulfur group elements, transition metals, alkali metal chalcogenide compounds, alkaline earth metal chalcogenide compounds, sulfur group elements amine salts, alkali metals, alkaline-earth metals, combinations thereof, and the like. In some cases, the co-solvent may not be necessary, and some mixed solutions do not need or use a co-solvent.

Combining the cadmium precursor solution with the selenium precursor solution may include stoichimetrically mixing the precursor solutions so that the desired stoichimetrical ratios of cadmium and selenium ions are present in order to form the desired quantum dot layer 12. In some embodiments, CdSe dissolved in a suitable non-aqueous solvent (such as any of those listed above) may be added to the mixed solution. In still other embodiments, the mixed solution may be formed by dissolving CdSe in an appropriate non-aqueous solvent.

Having formed the mixed solution, in some cases electron conductor layer 16 (e.g., prepared in the manner disclosed above) may be disposed in or otherwise coated with the mixed solution. This may include a non-vacuum deposition process, which may deposit a plurality of quantum dots (e.g., cadmium and selenium quantum dots) and/or quantum dot layer 12 (e.g., a cadmium and selenium quantum dot layer 12) on electron conductor layer 16. The deposition process may include any one of a variety of methods. For example, the deposition process may include dip coating, spin-coating, a flow-prolong method, spray deposition, screen printing, an infusion film-forming method, a roll coating method, a flat bar coating method, a capillary coating method, a Comma coating method, a gravure coating method, combinations thereof, and/or the like.

Once formed, quantum dot layer 12 may be dried, annealed, or both. Heating may include heating at ambient temperatures or at temperatures in the range of about 80-100° C. In some cases, annealing may be in the presence of H₂Se, Se, or vacuum. Annealing may also include heating at temperatures in the range of about 100-500° C. over 10 seconds to about 20 minutes. These are just examples. In some embodiments, annealing may include heating quantum dot layer 12 so that the physical properties of quantum dot layer 12 are altered so as to better adhere quantum dot layer 12 to electron conductor layer 16. In some embodiments, heating and/or annealing may be used to remove the non-aqueous solvents from the quantum dot layer 12.

In some embodiments, a shell may be disposed on the electron conductor layer 16 that has the cadmium and selenium quantum dot layer 12 already deposited thereon. The shell may include ZnS. In some cases, disposing the shell on electron conductor layer 16 may form or otherwise define a target photoelectrode for solar cell 10. The shell may function as an electron blocking/hole transport layer and, thus, may help prevent recombination of electrons with holes in this region of the solar cell 10.

It should be understood that this disclosure, in many respects, is only illustrative. Changes may be made in details, particularly in matters of shape, size, and arrangement of steps without exceeding the scope of the invention. The invention's scope is, of course, defined in the language in which the appended claims are expressed.

What is claimed is:

1. A method for manufacturing a solar cell, the method comprising:
dissolving a cadmium-containing compound in a first non-aqueous solvent to form a cadmium precursor solution;
dissolving a selenium-containing compound in a second non-aqueous solvent to form a selenium precursor solution;
combining the cadmium precursor solution with the selenium precursor solution to form a mixed solution;
exposing an electron conductor film to the mixed solution; and
wherein exposing the electron conductor film to the mixed solution causes a cadmium and selenium quantum dot layer to be provided on the electron conductor film.

2. The method of claim 1, wherein the cadmium-containing compound includes a cadmium-selenium compound, a cadmium-halogen compound, or both.

3. The method of claim 1, wherein the cadmium-containing compound includes one or more of CdSe, CdS, CdTe, CdCl₂, CdBr₂, and Cd(CH₃CO₂)₂.

4. The method of claim 1, wherein the selenium-containing compound includes a selenium-amine compound, a selenium-hydrazine compound, or both.

5. The method of claim 1, wherein the selenium-containing compound includes one or more of H₂Se, Na₂SeSO₃, selenourea, and a selenium-containing hydrazine compound.

6. The method of claim 1, wherein the first non-aqueous solvent is different from the second non-aqueous solvent.

7. The method of claim 1, wherein the first non-aqueous solvent is the same as the second non-aqueous solvent.

8. The method of claim 1, further comprising adding a co-solvent to the mixed solution.

9. The method of claim 1, wherein the first non-aqueous solvent, the second non-aqueous solvent, or both, include one or more of ammonia, a hydrazine compound, alcohol, ethanolamine, diethanolamine, triethanolamine, isopropanol amine, formamide, N,N-dimethyl-formamide, acetamide, N-methyl acetamide, N,N-dimethylacetamide, dimethyl sulfoxide, and polyvinylpyrrolidone.

10. The method of claim 1, wherein exposing the electron conductor film to the mixed solution includes dip coating.

11. The method of claim 1, wherein exposing the electron conductor film to the mixed solution includes a non-vacuum deposition process.

12. The method of claim 1, further comprising one or more of drying and annealing the electron conductor film having the cadmium and selenium quantum dot layer deposited thereon.

13. The method of claim 12, further comprising disposing a ZnS shell on the electron conductor film having a cadmium and selenium quantum dot layer deposited thereon.

14. The method of claim 13, wherein disposing a ZnS shell on the electron conductor film having a cadmium and selenium quantum dot layer deposited thereon forms a target photoelectrode.

15. A method for manufacturing a solar cell, the method comprising:
providing a cadmium-containing compound;
providing a selenium-containing compound;
providing a non-aqueous solvent;
combining the cadmium-containing compound, the selenium-containing compound, and the non-aqueous solvent to form a mixed solution;
exposing an electron conductor film to the mixed solution to provide a quantum dot layer on the electron conductor film, the quantum dot layer including a plurality of CdSe quantum dots; and
disposing a shell on the electron conductor film having the cadmium and selenium quantum dot layer deposited thereon.

16. The method of claim 15, wherein combining the cadmium-containing compound, the selenium-containing compound, and the non-aqueous solvent to form a mixed solution includes dissolving the cadmium-containing compound in the non-aqueous solvent, dissolving the selenium-containing compound in the non-aqueous solvent, and then combining the cadmium-containing compound dissolved in the non-aqueous solvent with the selenium-containing compound dissolved in the non-aqueous solvent.

17. The method of claim 15, wherein disposing a shell on the electron conductor film having the cadmium and selenium quantum dot layer deposited thereon includes disposing a ZnS shell on the electron conductor film having the cadmium and selenium quantum dot layer deposited thereon.

18. The method of claim 15, wherein the cadmium-containing compound includes one or more of CdSe, CdS, CdTe, CdCl₂, CdBr₂, and Cd(CH₃CO₂)₂.

19. The method of claim 15, wherein the selenium-containing compound includes one or more of H₂Se, Na₂SeSO₃, selenourea, and a selenium-containing hydrazine compound.

20. A quantum dot solar cell, comprising:
an electron conductor film having a mesoporous surface; and
a quantum dot layer deposited on the mesoporous surface using a single-step dip coating process where the electron conductor film is dipped into a mixed solution, the mixed solution being formed by:
providing a cadmium-containing compound,
providing a selenium-containing compound,
providing a non-aqueous solvent, and
combining the cadmium-containing compound, the selenium-containing compound, and the non-aqueous solvent to form the mixed solution.
